(19) United States
(12) Patent Application Publication
(10) Pub. No.: US 2013/0319515 A1
(43) Pub. Date: Dec. 5, 2013

(54) PHOTOELECTRIC CONVERSION DEVICE

(71) Applicant: SEMICONDUCTOR ENERGY LABORATORY CO., LTD., Atsugi-shi (JP)

(72) Inventor: Shunpei YAMAZAKI, Tokyo (JP)

(73) Assignee: SEMICONDUCTOR ENERGY LABORATORY CO., LTD., Atsugi-shi (JP)

(21) Appl. No.: 13/901,604

(22) Filed: May 24, 2013

(30) Foreign Application Priority Data
Jun. 1, 2012 (JP) 2012-126605

(51) Int. Cl. H01L 31/075

(52) U.S. Cl. CPC H01L 31/075
USPC 136/255; 438/85

(57) ABSTRACT

A photoelectric conversion device in which the amount of light loss due to light absorption in a window layer is small and which has favorable electrical characteristics is provided. The photoelectric conversion device has a structure in which a p-type first light-transmitting semiconductor layer, an i-type semiconductor layer comprising silicon, and an n-type second light-transmitting semiconductor layer are stacked between a pair of electrodes and has a p-i-n junction. The first light-transmitting semiconductor layer comprises an inorganic compound containing, as a main component, an oxide of a metal belonging to any of Groups 4 to 8. The second light-transmitting semiconductor layer comprises an oxide containing at least gallium.

### BACKGROUND OF THE INVENTION

1. Field of the Invention

The present invention relates to a photoelectric conversion device.

2. Description of the Related Art

In recent years, photoelectric conversion devices that do not produce carbon dioxide during power generation have attracted attention as a measure against global warming. As typical examples thereof, a bulk-type solar cell which uses a crystalline silicon substrate such as a single crystalline or polycrystalline silicon substrate and a thin-film type solar cell which uses a thin film such as an amorphous or microcrystalline silicon film have been known.

A thin-film type solar cell includes a thin film which can be formed using a required amount of silicon by a plasma CVD method or the like; thus, resource saving can be achieved as compared with the case of a bulk type solar cell. Further, by using a laser processing method, a screen printing method, or the like, the thin-film type solar cell can be easily formed in an integral manner and the solar cell with a large area can be easily obtained; thus, manufacturing cost can be reduced. However, the thin-film type solar cell has a disadvantage in lower conversion efficiency than the bulk-type solar cell.

In order to improve the conversion efficiency of the thin-film type solar cell, a method in which silicon oxide is used instead of silicon as a material of a p-type semiconductor layer serving as a window layer has been disclosed (for example, see Patent Document 1). A non-single-crystal-silicon-based p-type semiconductor layer formed as a thin film has substantially the same light absorption property as an i-type semiconductor layer which is a light absorption layer, which causes light loss due to light absorption. An object of the technique disclosed in Patent Document 1 is to suppress light loss due to light absorption in the window layer by using silicon oxide having a larger optical band gap than silicon as a material of the p-type semiconductor layer.

As an alternative method for suppressing light loss due to light absorption in a window layer, a technique in which an inversion layer induced by the field effect on the window layer side is used as a p-type semiconductor layer or an n-type semiconductor layer has been proposed. In this technique, a light-transmitting dielectric or conductor is formed over an n-i or p-i structure, and an electric field is applied to form an n-i-p or p-i-n junction.

### REFERENCE

### Patent Document

[Patent Document 1] Japanese Published Patent Application No. H07-130661

### SUMMARY OF THE INVENTION

In the solar cell in which silicon oxide is used as a material of a p-type semiconductor layer serving as a window layer, light loss due to light absorption in the window layer is reduced, so that the rate of light which reaches a light absorption layer is increased. However, in the silicon oxide having a larger band gap than silicon, resistance is not sufficiently reduced; thus, the loss of current due to resistance is a problem to be solved for further improvement in the characteristics.

In addition, although the field effect photoelectric conversion device can increase the rate of light which reaches the i-type semiconductor layer that is a light absorption layer, it has many technical difficulties; for example, relatively high voltage is needed for formation of the inversion layer. For this reason, commercialization has not been achieved.

In view of the above problems, an object of one embodiment of the present invention is to provide a photoelectric conversion device in which the amount of light loss due to light absorption in a window layer is small. Another object is to provide a photoelectric conversion device with favorable electrical characteristics.

One embodiment of the present invention disclosed in this specification relates to a p-i-n junction photoelectric conversion device which includes, as a window layer, a light-transmitting semiconductor layer comprising an inorganic compound containing an oxide of a metal belonging to any of Groups 4 to 8 as its main component.

An embodiment of the present invention disclosed in this specification is a photoelectric conversion device including a first light-transmitting semiconductor layer, a semiconductor layer comprising silicon, and a second light-transmitting semiconductor layer which are sequentially stacked between a pair of electrodes so that the semiconductor layer comprising silicon is in contact with the first light-transmitting semiconductor layer and the second light-transmitting semiconductor layer. The first light-transmitting semiconductor layer has a p-type conductivity. The semiconductor layer comprising silicon has an i-type conductivity. The second light-transmitting semiconductor layer has an n-type conductivity. The first light-transmitting semiconductor layer comprises an inorganic compound containing, as a main component, an oxide of a metal belonging to any of Groups 4 to 8. The second light-transmitting semiconductor layer comprises an oxide containing at least gallium.

It is to be noted that the ordinal numbers such as “first” and “second” in this specification, etc. are assigned in order to avoid confusion among components, and not intended to limit the number or order of the components.

The semiconductor layer comprising silicon is preferably non-single-crystal, amorphous, microcrystalline, or polycrystalline.

The band gap of the oxide of the metal contained in the first light-transmitting semiconductor layer is preferably larger than or equal to 2 eV.

Further, as the oxide of the metal contained in the first light-transmitting semiconductor layer, vanadium oxide, niobium oxide, tantalum oxide, chromium oxide, molybdenum oxide, tungsten oxide, manganese oxide, or rhenium oxide can be used.

It is preferable that the second light-transmitting semiconductor layer have a larger band gap than silicon and have a phase in which c-axes are aligned in a direction parallel to a normal vector of a formation surface or a normal vector of a top surface of the second light-transmitting semiconductor layer, in which atoms are arranged in a triangular or hexagonal configuration in the second light-transmitting semiconductor layer observed in a direction perpendicular to an a-b plane, and in which metal atoms are arranged in a layered manner or metal atoms and oxygen atoms are arranged in a layered manner in the second light-transmitting semiconductor layer observed in a direction perpendicular to the c-axes.

With use of one embodiment of the present invention, light loss due to light absorption in a window layer can be reduced. In addition, since the semiconductor layer in contact with the rear electrode has a light-transmitting property, the reflectance on the rear side can be increased. Thus, a photoelectric conversion device with favorable electric characteristics can be provided.

### BRIEF DESCRIPTION OF THE DRAWINGS

In the accompanying drawings:

FIG. 1 is a cross-sectional view illustrating a photoelectric conversion device of one embodiment of the present invention;

FIG. 2 is a cross-sectional view illustrating a photoelectric conversion device of one embodiment of the present invention;

FIGS. 3A and 3B each show I-V characteristics of an element in which a molybdenum oxide film is formed over a silicon substrate; and

FIG. 4 shows comparison of the light absorption coefficient between a molybdenum oxide film and an amorphous silicon film.

### DETAILED DESCRIPTION OF THE INVENTION

Embodiments of the present invention will be described in detail below with reference to the accompanying drawings. However, the present invention is not limited to the description below, and it is easily understood by those skilled in the art that modes and details disclosed herein can be modified in various ways. Therefore, the present invention is not construed as being limited to the description of the embodiments below. In the drawings for explaining the embodiments, the same portions or portions having similar functions are denoted by the same reference numerals, and description of such portions is not repeated in some cases.

### Embodiment 1

In this embodiment, a photoelectric conversion device of one embodiment of the present invention will be described.

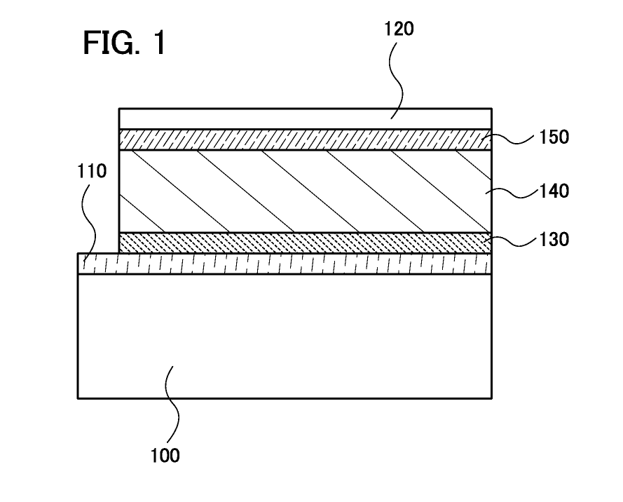

FIG. 1 is a cross-sectional view of a photoelectric conversion device in one embodiment of the present invention. A second electrode 110 that is a conductive film, a second light-transmitting semiconductor layer 130 that is an oxide semiconductor layer, a semiconductor layer comprising silicon 140, a first light-transmitting semiconductor layer 150 that comprises an inorganic compound, and a first electrode 120 that is a light-transmitting conductive film are sequentially stacked over a substrate 100. The first electrode 120 serves as a light-receiving plane of the photoelectric conversion device in FIG. 1. A conductive layer that includes a metal or a conductive resin may be provided as an auxiliary electrode over the first electrode 120.

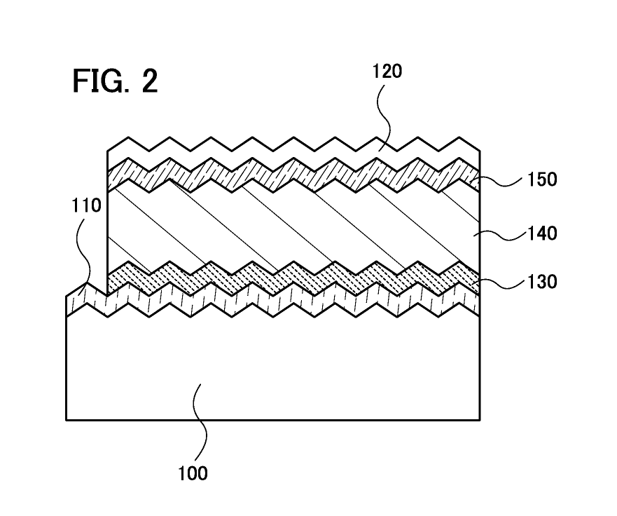

Alternatively, as illustrated in FIG. 2, a surface of the substrate 100 may be uneven. By making the surface of the substrate 100 uneven, each interface between layers stacked over the substrate 100 also becomes uneven. The unevenness causes multiple reflection at the substrate surface, an increase in the length of an optical path in the photoelectric conversion layer, and the total-reflection effect (light trapping effect) in which light reflected by the back surface is totally reflected by the front surface, so that the electrical characteristics of the photoelectric conversion device can be improved.

As the substrate 100, a glass substrate, a ceramic substrate, a metal substrate, a single-crystal silicon substrate, a SiC substrate, a GaN substrate, a GaAs substrate, or the like can be used. Alternatively, a substrate of a high-melting-point material such as quartz, alumina, sapphire, zirconia, aluminum nitride, or the like can be used, for example.

For the second electrode 110, a high-melting-point metal such as tungsten can be used. For the first electrode 120, for example, a light-transmitting conductive film including an indium tin oxide, an indium tin oxide containing silicon, an indium oxide containing zinc, a zinc oxide, a zinc oxide containing gallium, a zinc oxide containing aluminum, a tin oxide, a tin oxide containing fluorine, or a tin oxide containing antimony, or the like can be used. The above light-transmitting conductive film is not limited to a single layer and may have a stacked-layer structure including different films. For example, a stacked-layer structure of an indium tin oxide and a zinc oxide containing aluminum, a stacked-layer structure of an indium tin oxide and a tin oxide containing fluorine, or the like can be used.

As the auxiliary electrode provided over first electrode 120, a metal film of aluminum, titanium, nickel, silver, molybdenum, tantalum, tungsten, chromium, copper, stainless steel, or the like can be used. The metal film is not limited to a single layer and may have a stacked-layer structure including different films. The metal film may be formed using a conductive resin such as a silver paste, a copper paste, a nickel paste, or a molybdenum paste. Further, the metal film may be a stacked layer of different materials, such as a stacked layer of a silver paste and a copper paste. The conductive resin can be formed in such a manner that a conductive resin is applied by a screen printing method, a dispensing method, an ink-jet method or the like and then baked.

For the first light-transmitting semiconductor layer 150, it is possible to use an inorganic compound containing, as its main component, a transition metal oxide having a band gap of greater than or equal to 2 eV, preferably greater than or equal to 2.5 eV. It is particularly preferable that the inorganic compound be an oxide of a metal belonging to any of Groups 4 to 8 in the periodic table. The oxide of the metal has a high light-transmitting property with respect to a wavelength range where light absorption of silicon is exhibited.

Specifically, as the metal oxide, vanadium oxide, niobium oxide, tantalum oxide, chromium oxide, molybdenum oxide, tungsten oxide, manganese oxide, rhenium oxide, or the like can be used. Among these, molybdenum oxide is especially preferable because it can be easily treated due to its stability in the air and low hygroscopic property.

The conductivity type can be changed by adding an impurity to the metal oxide. Even in the case where an impurity is not intentionally added to the metal oxide, a defect in the metal oxide or a slight amount of an impurity introduced into the metal oxide during film formation may cause the metal oxide to exhibit p-type conductivity.

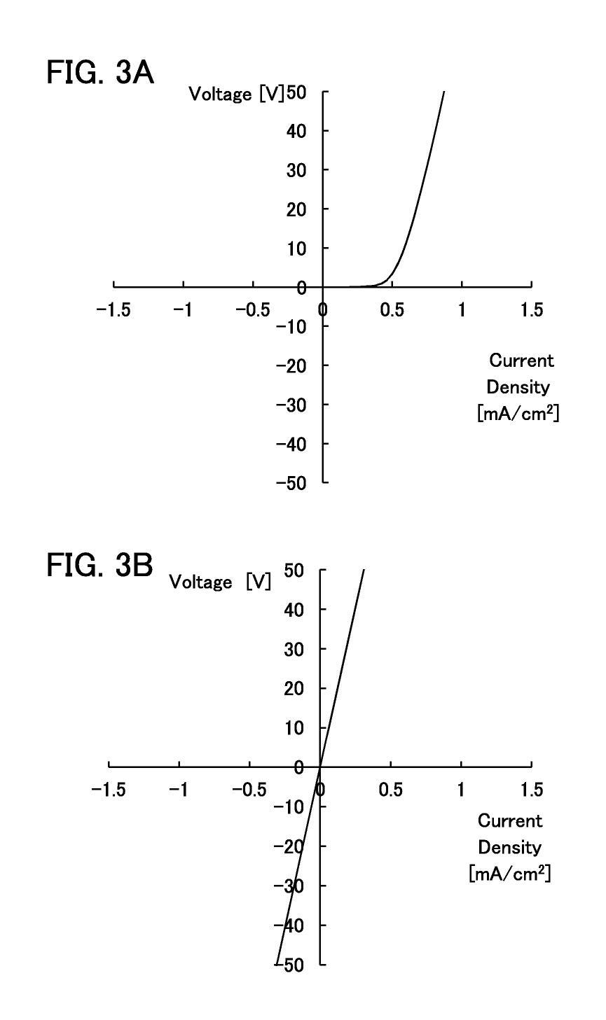

For example, when molybdenum trioxide powder (4N MOO03PB) manufactured by Kojundo Chemical Laboratory Co., Ltd. is put in a tungsten boat (BB-3) manufactured by Furuuchi Chemical Corporation, and vapor deposition using resistive heating is performed on silicon substrates at a deposition rate of 0.2 nm/sec in vacuum of less than or equal to 1×10⁻⁴ Pa, elements having different I-V characteristics are formed depending on the conductivity type of the silicon substrate. FIG. 3A shows I-V characteristics of an element in which a molybdenum oxide film is formed over an n-type silicon substrate by the above method, and FIG. 3B shows I-V characteristics of an element in which a molybdenum oxide film is formed over a p-type silicon substrate by the above method. FIG. 3A shows a rectifying property, and FIG. 3B shows an ohmic property. Accordingly, a p-n junction is formed in the element exhibiting the property in FIG. 3A. Thus, the molybdenum oxide films formed in the above method are found to have a p-type conductivity.

Note that the electric conductivity, the refractive index, the extinction coefficient, and the band gap obtained from a Tauc plot of the molybdenum oxide film formed by the above vapor deposition method are 2×10⁻⁶ S/cm to 3.8×10⁻³ S/cm (dark conductivity), 1.6 to 2.2 (wavelength: 550 nm), 6×10⁻⁴ to 3×10⁻³ (wavelength: 550 nm), and 2.8 eV to 3 eV, respectively.

Further, the metal oxide has a high passivation effect and can reduce defects on a surface of silicon, which can improve the lifetime of carriers.

For example, it was determined by a μPCD (microwave detected photoconductivity decay) method that the carrier lifetime of an n-type single crystal silicon substrate having a resistivity of about 9 Ω-cm in the case of depositing molybdenum oxide on both surfaces of the substrate as passivation films is about 400 μsec. Further, the lifetime of an n-type single crystal silicon substrate, on which chemical passivation using an alcoholic iodine solution has been performed, is also about 400 μsec. The lifetime of an n-type single crystal silicon substrate on which a passivation film is not formed is about 40 μsec.

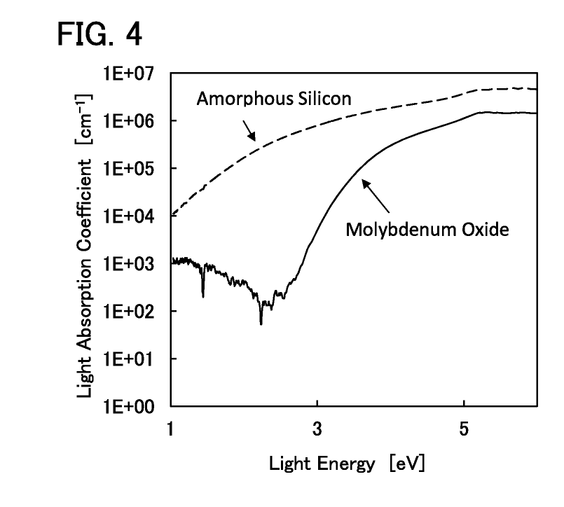

In FIG. 4, the light absorption coefficient of a molybdenum oxide film formed over a glass substrate by the above vapor deposition method is compared with that of an amorphous silicon film formed by a plasma CVD method, which is a comparative example. The light absorption coefficient of the molybdenum oxide film is small in a wide wavelength range.

For the semiconductor layer comprising silicon 140, an i-type silicon semiconductor can be used. Note that in this specification, an “i-type semiconductor” refers not only to what is called an intrinsic semiconductor in which the Fermi level lies in the middle of the band gap, but also to a semiconductor in which the concentration of each of an impurity imparting p-type conductivity and an impurity imparting n-type conductivity is less than or equal to 1×10¹⁸ cm⁻³, and in which the photoconductivity is higher than the dark conductivity.

As the i-type silicon semiconductor used in the semiconductor layer comprising silicon 140, it is preferable to use non-single-crystal silicon, amorphous silicon, microcrystalline silicon, or polycrystalline silicon. Amorphous silicon has a peak of spectral sensitivity in the visible light region; thus, with use of amorphous silicon, a photoelectric conversion device having a high photoelectric conversion ability in an environment with low illuminance such as a place under a fluorescent lamp can be formed. Further, microcrystalline silicon and polycrystalline silicon each have a peak of spectral sensitivity on the longer wavelength side than the visible light region; thus, with use of microcrystalline silicon or polycrystalline silicon, a photoelectric conversion device having a high photoelectric conversion ability in the outdoors where a light source is sunlight can be formed.

The thickness of the semiconductor layer comprising silicon 140 in the case of using amorphous silicon is preferably more than or equal to 100 nm and less than or equal to 600 nm, and the thickness in the case of using microcrystalline silicon or polycrystalline silicon is preferably more than or equal to 1 μm and less than or equal to 100 μm. Note that an i-type silicon semiconductor can be deposited by a plasma CVD method or the like using silane or disilane as a source gas.

As the second light-transmitting semiconductor layer 130, an n-type oxide semiconductor layer having a crystal structure can be used; the oxide semiconductor layer is preferably an oxide containing at least gallium.

The second light-transmitting semiconductor layer 130 may be an oxide containing at least In and a metal element M (M is Ga, Hf, Zn, Mg, Sn, or the like). For example, an In—Zn-based oxide, an In—Mg-based oxide, an In—Ga-based oxide, an In—Ga—Zn-based oxide (also referred to as IGZO), an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Sn—Hf—Zn-based oxide, or the like can be used.

A structure of an oxide semiconductor film is described below. In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

In this specification, the trigonal and rhombohedral crystal systems are included in the hexagonal crystal system.

An oxide semiconductor film is classified roughly into a single-crystal oxide semiconductor film and a non-single-crystal oxide semiconductor film. The non-single-crystal oxide semiconductor film includes any of an amorphous oxide semiconductor film, a microcrystalline oxide semiconductor film, a polycrystalline oxide semiconductor film, a c-axis aligned crystalline oxide semiconductor (CAAC-OS) film, and the like.

The amorphous oxide semiconductor film has disordered atomic arrangement and no crystalline component. A typical example thereof is an oxide semiconductor film in which no crystal part exists even in a microscopic region, and the whole of the film is amorphous.

The microcrystalline oxide semiconductor film includes a microcrystal (also referred to as nanocrystal) with a size greater than or equal to 1 nm and less than 10 nm, for example. Thus, the microcrystalline oxide semiconductor film has a higher degree of atomic order than the amorphous oxide semiconductor film. Hence, the density of defect states of the microcrystalline oxide semiconductor film is lower than that of the amorphous oxide semiconductor film.

The CAAC-OS film is one of oxide semiconductor films including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm. The density of defect states of the CAAC-OS film is lower than that of the microcrystalline oxide semiconductor film. The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface of the CAAC-OS film. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ do not appear at around 36°.

In a transistor using the CAAC-OS film, change in electric characteristics due to irradiation with visible light or ultraviolet light is small. Thus, the transistor has high reliability.

Note that an oxide semiconductor film may be a stacked film including two or more films of an amorphous oxide semiconductor film, a microcrystalline oxide semiconductor film, and a CAAC-OS film, for example.

For example, the CAAC-OS film is formed by a sputtering method using a polycrystalline oxide semiconductor sputtering target. When ions collide with the sputtering target, a crystal region included in the sputtering target may be separated from the target along an a-b plane; in other words, a sputtered particle having a plane parallel to an a-b plane (flat-plate-like sputtered particle or pellet-like sputtered particle) may flake off from the sputtering target. In that case, the flat-plate-like sputtered particle reaches a substrate in the state of maintaining its crystal state, whereby the crystal state of the sputtering target is transferred to the substrate and the CAAC-OS film can be formed.

For the deposition of the CAAC-OS film, the following conditions are preferably used.

By reducing the concentration of impurities during the deposition, the crystal state can be prevented from being broken by the impurities. For example, impurities (e.g., hydrogen, water, carbon dioxide, or nitrogen) which exist in the deposition chamber may be reduced. Furthermore, impurities in a deposition gas may be reduced. Specifically, a deposition gas whose dew point is −80° C. or lower, preferably −100° C. or lower is used.

By increasing the substrate heating temperature during the deposition, migration of a sputtered particle is likely to occur after the sputtered particle is attached to a substrate surface. Specifically, the substrate heating temperature during the deposition is higher than or equal to 100° C. and lower than or equal to 740° C., preferably higher than or equal to 200° C. and lower than or equal to 500° C. By increasing the substrate heating temperature during the deposition, when the flat-plate-like sputtered particle reaches the substrate, migration occurs on the substrate surface, so that a flat plane of the flat-plate-like sputtered particle is attached to the substrate.

Furthermore, it is preferable that the proportion of oxygen in the deposition gas be increased and the power be optimized in order to reduce plasma damage at the deposition. The proportion of oxygen in the deposition gas is 30 vol % or higher, preferably 100 vol %.

As an example of the sputtering target, an In—Ga—Zn—O compound target is described below.

The In—Ga—Zn—O compound target, which is polycrystalline, is made by mixing InO_{X} powder, GaO_{Y} powder, and ZnO_{Z} powder in a predetermined ratio, applying pressure, and performing heat treatment at a temperature higher than or equal to 1000° C. and lower than or equal to 1500° C. Note that X, Y, and Z are each a given positive number. Here, the predetermined ratio of InO_{X} powder to GaO_{Y} powder and ZnO_{Z} powder is, for example, 2:2:1, 8:4:3, 3:1:1, 1:1:1, 4:2:3, or 3:1:2 in molar ratio. The kinds of powder and the mixing ratio may be determined as appropriate depending on the desired sputtering target.

The oxide semiconductor film having the above crystal structure can have an n-type conductivity by selectively adding phosphorus, boron, or nitrogen to the oxide semiconductor film. After the addition of phosphorus, boron, or nitrogen, the oxide semiconductor film is subjected to heat treatment at 900° C. or more and 1500° C. or less.

A region to which phosphorus, boron, or nitrogen is added in the oxide semiconductor film having the crystal structure tends to be amorphous. By leaving a crystal part in the oxide semiconductor film and performing heat treatment thereon at 900° C. or more and 1500° C. or less, a CAAC-OS film can be formed again. The heat treatment at 900° C. or more and 1500° C. or less can increase the density of the oxide semiconductor film. Further, with the heat treatment at 900° C. or more and 1500° C. or less, density and crystallinity which are in substantially the same level as those of a single crystal of an oxide semiconductor can be obtained.

A p-i-n junction can be formed in the above-described stacked layers of the p-type first light-transmitting semiconductor layer 150, the i-type semiconductor layer comprising silicon 140, and the n-type second light-transmitting semiconductor layer 130. Thus, a photoelectric conversion device of one embodiment of the present invention can be manufactured.

In conventional photoelectric conversion devices, amorphous silicon or microcrystalline silicon whose resistance is lowered by addition of impurities, or the like is used as a material of a window layer; thus, the window layer has a light absorption property equivalent to that of the light absorption layer. Although photo-carriers are generated in the window layer, the lifetime of minority carriers is short and the carriers cannot be taken out as current. Thus, the light absorption in the window layer is a heavy loss in the conventional photoelectric conversion devices.

In one embodiment of the present invention, the light-transmitting semiconductor layer formed using an inorganic compound is used as a window layer, whereby the light loss due to light absorption in the window layer is reduced and photoelectric conversion can be efficiently performed in the i-type light absorption layer. In addition, as described above, the inorganic compound has extremely high passivation effect on the silicon surface. Accordingly, the photoelectric conversion efficiency of the photoelectric conversion device can be improved.

By providing the second light-transmitting semiconductor layer, an interface having high birefringence is generated between the second light-transmitting semiconductor layer and the second electrode 110; thus, the reflectance can be improved, which can lengthen a substantial optical path length in the semiconductor layer comprising silicon which is a light absorption layer. That is, use efficiency of light can be increased, so that conversion efficiency of the photoelectric conversion device can be improved. Note that the thickness of the light-transmitting conductive film is preferably 10 nm or more and 100 nm or less.

This embodiment can be implemented in free combination with any of other embodiments.

### Embodiment 2

In this embodiment, a method for manufacturing the photoelectric conversion device described in Embodiment 1 with reference to FIG. 1 is described.

First, a conductive film serving as the second electrode 110 is formed over the substrate 100. Here, a tungsten film is formed by a sputtering method. Note that a quartz substrate is used as the substrate 100 in this embodiment.

Next, the second light-transmitting semiconductor layer 130 is formed over the second electrode 110. As the light-transmitting semiconductor layer, any of the oxide semiconductor layers described in Embodiment 1 can be used.

The oxide semiconductor film is preferably the one having a crystal structure right after deposition, which is obtained by deposition by a sputtering method at a relatively high deposition temperature. If the deposition temperature is set at 400° C. or more for high density, later heat treatment at 900° C. or more does not generate peeling or the like. Note that in the case where the oxide semiconductor film has an amorphous structure right after the deposition, the oxide semiconductor film can be changed to have a crystal structure by performing heat treatment thereon.

Then, heat treatment is performed at 900° C. or more and 1500° C. or less in a vacuum atmosphere, a nitrogen atmosphere, an oxygen atmosphere, or a mixed atmosphere of nitrogen and oxygen. With the heat treatment at 900° C. or more and 1500° C. or less, density and crystallinity which are in substantially the same level as those of a single crystal of an oxide semiconductor can be obtained.

After the oxide semiconductor film having a crystal structure is formed, phosphorus, boron, or nitrogen is added to the vicinity of a surface of the oxide semiconductor film by plasma treatment or an ion introduction method. A region to which phosphorus, boron, or nitrogen is added tends to be amorphous. It is preferable that a crystal part remain under the region to which phosphorus, boron, or nitrogen is added. After the addition, heat treatment is performed at 900° C. or more and 1500° C. or less in a vacuum atmosphere, a nitrogen atmosphere, an oxygen atmosphere, or a mixed atmosphere of nitrogen and oxygen. This heat treatment can crystallize the region to which phosphorus, boron, or nitrogen is added.

Next, by a plasma CVD method, an i-type amorphous silicon film is formed with a thickness of 400 nm as the semiconductor layer comprising silicon 140. As a source gas, silane or disilane can be used, and hydrogen may be added thereto. At this time, an atmospheric component contained in the layer serves as a donor in some cases; therefore, boron (B) may be added to the source gas so that the conductivity type is closer to i-type. In this case, the concentration of boron in the i-type amorphous silicon is made to be higher than or equal to 0.001 at. % and lower than or equal to 0.1 at. %.

Next, the first light-transmitting semiconductor layer 150 is formed over the semiconductor layer comprising silicon 140. In the example described in this embodiment, a p-type molybdenum oxide film is formed as the first light-transmitting semiconductor layer 150.

The p-type molybdenum oxide film can be formed by a vapor phase method such as a vapor deposition method, a sputtering method, or an ion plating method. As a vapor deposition method, a method in which a material of molybdenum oxide alone is vapor-deposited, or a method in which a material of molybdenum oxide and an impurity imparting p-type conductivity are co-evaporated and deposited may be used. Note that the co-evaporation refers to an evaporation method in which evaporation of materials from a plurality of evaporation sources is carried out at the same time in one treatment chamber. As a sputtering method, a method in which molybdenum oxide, molybdenum, or any of the above materials which contains an impurity imparting p-type conductivity is used as a target, and oxygen or a mixed gas of oxygen and a rare gas such as argon is used as a sputtering gas may be used. As an ion plating method, a method in which a film is formed in plasma containing oxygen using a material similar to the material used in the sputtering method described above may be used.

In this embodiment, a method in which a material of molybdenum oxide alone is vapor-deposited is used, and powder of molybdenum oxide is used as an evaporation source. The vapor deposition is preferably performed in a high vacuum of 5×10⁻³ Pa or less, preferably 1×10⁻⁴ Pa or less.

Next, the first electrode 120 is formed over the first light-transmitting semiconductor layer 150. The first electrode 120 can be formed by a sputtering method or the like using indium tin oxide or the like.

In the above-described manner, the photoelectric conversion device of one embodiment of the present invention can be formed.

This embodiment can be implemented in free combination with any of other embodiments.

This application is based on Japanese Patent Application serial no. 2012-126605 filed with Japan Patent Office on Jun. 1, 2012, the entire contents of which are hereby incorporated by reference.

What is claimed is:

1. A photoelectric conversion device comprising:
a second electrode;
a second light-transmitting semiconductor layer having an n-type conductivity on the second electrode;
a semiconductor layer having an i-type conductivity on the second light-transmitting semiconductor layer;
a first light-transmitting semiconductor layer having a p-type conductivity on the semiconductor layer; and
a first electrode on the first light-transmitting semiconductor layer,
wherein the first light-transmitting semiconductor layer comprises an oxide of a metal belonging to any of Groups 4 to 8, and
wherein the second light-transmitting semiconductor layer comprises an oxide of at least one metal selected from indium, gallium, hafnium, zinc, magnesium, and tin.

2. The photoelectric conversion device according to claim 1, wherein the semiconductor layer comprises one of non-single-crystal silicon, amorphous silicon, microcrystalline silicon, and polycrystalline silicon.

3. The photoelectric conversion device according to claim 1, wherein the first light-transmitting semiconductor layer has a band gap of larger than or equal to 2 eV.

4. The photoelectric conversion device according to claim 1, wherein the first light-transmitting semiconductor layer comprises one of vanadium oxide, niobium oxide, tantalum oxide, chromium oxide, molybdenum oxide, tungsten oxide, manganese oxide, and rhenium oxide.

5. The photoelectric conversion device according to claim 1, wherein the second light-transmitting semiconductor layer comprises at least gallium and oxygen.

6. The photoelectric conversion device according to claim 1, wherein the second light-transmitting semiconductor layer comprises at least indium, gallium, and oxygen.

7. The photoelectric conversion device according to claim 1,
wherein the second light-transmitting semiconductor layer has a larger band gap than silicon,
wherein the second light-transmitting semiconductor layer has a phase in which c-axes are aligned in a direction parallel to one of a normal vector of a formation surface and a normal vector of a top surface of the second light-transmitting semiconductor layer,
wherein, in the second light-transmitting semiconductor layer, atoms are arranged in one of a triangular configuration and a hexagonal configuration when the second light-transmitting semiconductor layer is observed in a direction perpendicular to an a-b plane, and
wherein, in the second light-transmitting semiconductor layer, metal atoms are arranged in a layered manner or both metal atoms and oxygen atoms are arranged in a layered manner when the second light-transmitting semiconductor layer is observed in a direction perpendicular to the c-axes.

8. A photoelectric conversion device comprising:
a substrate
a second electrode on the substrate;
a second light-transmitting semiconductor layer having an n-type conductivity on the second electrode;
a semiconductor layer having an i-type conductivity on the second light-transmitting semiconductor layer;
a first light-transmitting semiconductor layer having a p-type conductivity on the semiconductor layer; and
a first electrode on the first light-transmitting semiconductor layer,
wherein the first light-transmitting semiconductor layer comprises an oxide of a metal belonging to any of Groups 4 to 8, and
wherein the second light-transmitting semiconductor layer comprises indium, oxygen, and at least one metal selected from gallium, hafnium, zinc, magnesium, and tin.

9. The photoelectric conversion device according to claim 8, wherein the semiconductor layer comprises one of non-single-crystal silicon, amorphous silicon, microcrystalline silicon, and polycrystalline silicon.

10. The photoelectric conversion device according to claim 8, wherein the first light-transmitting semiconductor layer has a band gap of larger than or equal to 2 eV.

11. The photoelectric conversion device according to claim 8, wherein the first light-transmitting semiconductor layer comprises one of vanadium oxide, niobium oxide, tantalum oxide, chromium oxide, molybdenum oxide, tungsten oxide, manganese oxide, and rhenium oxide.

12. The photoelectric conversion device according to claim 8, wherein the substrate has an uneven surface.

13. The photoelectric conversion device according to claim 8,
wherein the second light-transmitting semiconductor layer has a larger band gap than silicon,
wherein the second light-transmitting semiconductor layer has a phase in which c-axes are aligned in a direction parallel to one of a normal vector of a formation surface and a normal vector of a top surface of the second light-transmitting semiconductor layer,
wherein, in the second light-transmitting semiconductor layer, atoms are arranged in one of a triangular configuration and a hexagonal configuration when the second light-transmitting semiconductor layer is observed in a direction perpendicular to an a-b plane, and
wherein, in the second light-transmitting semiconductor layer, metal atoms are arranged in a layered manner or both metal atoms and oxygen atoms are arranged in a layered manner when the second light-transmitting semiconductor layer is observed in a direction perpendicular to the c-axes.

14. A method for manufacturing a photoelectric conversion device, comprising the steps of:
forming a second electrode on a substrate;
forming a second light-transmitting semiconductor layer having an n-type conductivity on the second electrode;
forming a semiconductor layer comprising silicon having an i-type conductivity on the second light-transmitting semiconductor layer;
forming a first light-transmitting semiconductor layer having a p-type conductivity on the semiconductor layer; and
forming a first electrode on the first light-transmitting semiconductor layer,
wherein the first light-transmitting semiconductor layer comprises an oxide of a metal belonging to any of Groups 4 to 8, and
wherein the second light-transmitting semiconductor layer comprises an oxide of at least one metal selected from indium, gallium, hafnium, zinc, magnesium, and tin.

15. The method according to claim 14, wherein the substrate has an uneven surface.

16. The method according to claim 14, wherein the semiconductor layer comprises one of non-single-crystal silicon, amorphous silicon, microcrystalline silicon, and polycrystalline silicon.

17. The method according to claim 14, wherein the first light-transmitting semiconductor layer has a band gap of larger than or equal to 2 eV.

18. The method according to claim 14, wherein the first light-transmitting semiconductor layer comprises one of vanadium oxide, niobium oxide, tantalum oxide, chromium oxide, molybdenum oxide, tungsten oxide, manganese oxide, and rhenium oxide.

19. The method according to claim 14, further comprising a step of selectively adding one of phosphorus, boron, and nitrogen to the second light-transmitting semiconductor layer.

20. The method according to claim 14, further comprising a step of heating the second light-transmitting semiconductor layer at 900° C. or more and 1500° C. or less.
